(19) United States
(12) Patent Application Publication
(10) Pub. No.: US 2019/0352535 A1
(43) Pub. Date: Nov. 21, 2019

(54) Chemical Mechanical Polishing Tungsten Buffing Slurries

(71) Applicant: Versum Materials US, LLC, Tempe, AZ (US)

(72) Inventors: Xiaobo Shi, Tempe, AZ (US); Dennis Kim, Pangyo (KR); Chun Lu, Tempe, AZ (US); Mark Leonard O'Neill, Tempe, AZ (US)

(73) Assignee: Versum Materials US, LLC, Tempe, AZ (US)

(21) Appl. No.: 16/414,093

(22) Filed: May 16, 2019

Related U.S. Application Data
(60) Provisional application No. 62/674,363, filed on May 21, 2018.

(51) Int. Cl. C09G 1/02; H01L 21/321

(52) U.S. Cl. CPC C09G 1/02; H01L 21/3212

(57) ABSTRACT

Tungsten chemical mechanical polishing (CMP) buff or barrier compositions and related method and system are disclosed. The compositions comprise abrasive; solid state or water soluble catalyst; corrosion inhibitor for W of an oligomer or polymer comprising ethyleneimine unit, propyleneimine unit, and combinations thereof; chemical additive of polystyrene sulfonic acid or polyacrylic acid, their ammonium salts, potassium salt or sodium salts having molecular weight ranged from 1,000 to 2,000,000; solvent; and acidic pH. The compositions afford low dishing and low erosion levels in the polished substrate while simultaneously afford relative high oxide removal rates, high barrier film removal rates and low W removal rates.

### CROSS REFERENCE TO RELATED PATENT APPLICATIONS

The present patent application claims the benefit of U.S. Provisional Patent Application Ser. No. 62/674,363 filed May 21, 2018.

### BACKGROUND OF THE INVENTION

This invention relates generally to the chemical-mechanical planarization (CMP) of tungsten-containing substrates on semiconductor wafers and slurry compositions therefor. This invention is especially useful for tungsten CMP buff and barrier applications where low dishing/plug recess and low array erosion on planarized substrates is desired and/or required.

Chemical mechanical planarization (chemical mechanical polishing, CMP) for planarization of semiconductor substrates is now widely known to those skilled in the art and has been described in numerous patents and open literature publications. An introductory reference on CMP is as follows: “Chemical-Mechanical Polish” by G. B. Shinn et al., Chapter 15, pages 415-460, in Handbook of Semiconductor Manufacturing Technology, editors: Y. Nishi and R. Doering, Marcel Dekker, New York City (2000).

In a typical CMP process a substrate (e.g., a wafer) is placed in contact with a rotating polishing pad attached to a platen. A CMP slurry (or composition, they are exchangeable), typically an abrasive and chemically reactive mixture, is supplied to the pad during CMP processing of the substrate. During the CMP process, the pad (fixed to the platen) and substrate are rotated while a wafer carrier system or polishing head applies pressure (downward force) against the substrate. The slurry accomplishes the planarization (polishing) process by chemically and mechanically interacting with the substrate film being planarized due to the effect of the rotational movement of the pad parallel to the substrate. Polishing is continued in this manner until the desired film on the substrate is removed with the usual objective being to effectively planarize the substrate. Typically, metal CMP slurries contain an abrasive material, such as silica or alumina, suspended in an oxidizing, aqueous medium.

There are a large number of materials used in the manufacture of integrated circuits such as a semiconductor wafer. The materials generally fall into three categories—dielectric material, adhesion and/or barrier layers, and conductive layers. The use of the various substrates, e.g., dielectric material such as Tetraethyl Orthosilicate (TEOS), Plasma Enhanced Tetraethyl Orthosilicate (PETEOS), and low-k dielectric materials; barrier/adhesion layers such as tantalum, titanium, tantalum nitride, and titanium nitride; and conductive layers such as copper, aluminum, tungsten, and noble metals are known in the industry.

Integrated circuits are interconnected through the use of well-known multilevel interconnections. Interconnection structures normally have a first layer of metallization, an interconnection layer, a second level of metallization, and typically third and subsequent levels of metallization. Interlevel dielectric materials such as silicon dioxide and sometimes low-k materials are used to electrically isolate the different levels of metallization in a silicon substrate or well. The electrical connections between different interconnection levels are made through the use of metallized vias and in particular tungsten vias. U.S. Pat. No. 4,789,648 describes a method for preparing multiple metallized layers and metallized vias in insulator films. In a similar manner, metal contacts are used to form electrical connections between interconnection levels and devices formed in a well. The metal vias and contacts are generally filled with tungsten and generally employ an adhesion layer such as titanium nitride (TiN) and/or titanium to adhere a metal layer such as a tungsten metal layer to the dielectric material.

In one semiconductor manufacturing process, metallized vias or contacts are formed by a blanket tungsten deposition followed by a CMP step. In a typical process, via holes are etched through the interlevel dielectric (ILD) to interconnection lines or to a semiconductor substrate. Next, a thin adhesion layer such as titanium nitride and/or titanium is generally formed over the ILD and is directed into the etched via hole. Then, a tungsten film is blanket deposited over the adhesion layer and into the via. The deposition is continued until the via hole is filled with tungsten. Finally, the excess tungsten is removed by chemical mechanical polishing (CMP) to form metal vias.

The ratio of the removal rate of a metal (e.g., tungsten) to the removal rate of a dielectric base is called the “selectivity” for removal of the metal in relation to removal of the dielectric during CMP processing of substrates comprised of metal and dielectric material.

When CMP slurries with high selectivity for removal of metal in relation to dielectric are used, the metal layers are easily over-polished creating a depression or “dishing” effect in the metalized areas. This feature distortion is unacceptable due to lithographic and other constraints in semiconductor manufacturing.

Another feature distortion that is unsuitable for semiconductor manufacturing is called “erosion.” Erosion is the topography difference between a field of dielectric and a dense array of metal vias or trenches. In CMP, the materials in the dense array may be removed or eroded at a faster rate than the surrounding field of dielectric. This causes a topography difference between the field of dielectric and the dense metal (e.g., copper or tungsten) array.

As industry standards trend toward smaller device features, there is an ever-developing need for CMP slurries that deliver superior planarization of the nanostructures of IC chips. Specifically, for 45 nm technology nodes and smaller feature sizes, slurry products must deliver low removal rate selectivity between metal and dielectric, thereby lowering erosion while maintaining sufficient removal rate and low defect levels. Furthermore, in the competitive market of CMP consumables, low cost of ownership, specifically through concentration of CMP slurry, is quickly becoming an industry standard.

A typically used CMP slurry has two actions, a chemical component and a mechanical component. An important consideration in slurry selection is “passive etch rate.” The passive etch rate is the rate at which a metal (e.g., copper) is dissolved by the chemical component alone and should be significantly lower than the removal rate when both the chemical component and the mechanical component are involved. A large passive etch rate leads to dishing of the metallic trenches and vias, and thus, preferably, the passive etch rate is less than 10 nanometers per minute.

These are three general types of layers that can be polished. The first layer is interlayer dielectrics (ILD), such as silicon oxide and silicon nitride. The second layer is metal layers such as tungsten, copper, aluminum, etc., which are used to connect the active devices. This application addresses polishing the metal layer, particularly tungsten. The third type of layer is an adhesion/barrier layer such as titanium nitride.

In the case of CMP of metals, the chemical action is generally considered to take one of two forms. In the first mechanism, the chemicals in the solution react with the metal layer to continuously form an oxide layer on the surface of the metal. This generally requires the addition of an oxidizer to the solution such as hydrogen peroxide, ferric nitrate, etc. Then the mechanical abrasive action of the particles continuously and simultaneously removes this oxide layer which is formed on the metal layer. A judicious balance of these two processes obtains optimum results in terms of removal rate and polished surface quality.

In the second mechanism, no protective oxide layer is formed. Instead, the constituents in the solution chemically attack and dissolve the metal, while the mechanical action is largely one of mechanically enhancing the dissolution rate by such processes as continuously exposing more surface area to chemical attack, raising the local temperature (which increases the dissolution rate) by the friction between the particles and the metal and enhancing the diffusion of reactants and products to and away from the surface by mixing and by reducing the thickness of the boundary layer.

W CMP buff or barrier process is a key CMP step post-W bulk CMP. After removal of overburden W layers through W bulk CMP process, the following up CMP step is called W CMP buff or barrier process in which the W patterned wafers will be further polished for achieving improved planarity across the whole patterned wafers and improving W plug recess or W trench dishing, thus, increasing the fabrication yield of integrated electronic chips.

The slurry composition is an important factor in the CMP step. Depending on the choice of the oxidizing agent, the abrasive, and other useful additives, the polishing slurry can be tailored to provide effective polishing of metal layers at desired polishing rates while minimizing surface imperfections, defects, corrosion, and erosion of oxide in areas with tungsten vias. Furthermore, the polishing slurry may be used to provide controlled polishing selectivity to other thin-film materials used in current integrated circuit technology such as titanium, titanium nitride and the like.

There is a significant need for tungsten CMP process and slurry(s) which includes W CMP buffing or barrier slurries that afford low dishing and plug recess effects especially since the semiconductor industry continues to move towards smaller and smaller feature sizes.

### BRIEF SUMMARY OF THE INVENTION

The needs are satisfied by using the disclosed compositions, methods, and planarization systems for W buff or barrier polishing of a substrate comprising tungsten, dielectric films such as oxide films, and barrier films such as TiN or Ti or TaN or Ta.

In one aspect, CMP polishing compositions are provided for CMP of for W buff or barrier polishing. The CMP polishing composition comprises:

abrasive,

catalyst,

corrosion inhibitor for W,

chemical additive to reduce the erosion and W trench dishing,

oxidizing agent,

pH adjusting agent, and

solvent,

pH ranges are from 2.0 to 8.0, 2 to 6.5, 2.0 to 4, 2.0 to 3.0, or 2.0 to 2.5.

The abrasive includes but is not limited to alumina, ceria, germania, silica, high purity colloidal silica, titania, zirconia, composite particles abrasive such as ceria-coated silica, silica-coated alumina, and combinations thereof. High purity colloidal silica or colloidal silica are preferred abrasives.

The catalyst includes solid-state and water soluble catalysts.

The solid-state catalyst includes but is not limited to Iron-coated silica or iron-coated inorganic metal oxide, such as iron-coated alumina, iron-coated titania, iron-coated zirconia, iron-coated organic polymeric nano-sized particles. These iron-coated nano-sized particles can have spherical shapes, cocoon shape, aggregate shape or any other shapes.

The water soluble catalyst includes metal-ligand complexes have the general molecular structures depicted as below:

M(n+)-Lm

The metal ion M in metal-ligand complexes includes, but is not limited to, cesium, Ce, Ru, Os, Co, Rh, Ir, Ni, Pd, Pt, Cu, Ag, Au ions and other metal ions.

n+ indicates the oxidation number of metal ions in metal-ligand complexes and is 1+, 2+, or 3+ or other positive charges.

In general, the ligand molecule L used in forming metal-ligand complexes includes, but is not limited to, the organic amines, organic acids with mono-, bi-, tri-, tetra- or more carboxylic functional groups, sulfonic or phosphoric acid functional groups, organic acid salts (ammonium salts, potassium salts or sodium salts) with mono-, bi-, tri-, tetra- or more carbonate or sulfonate or phosphate functional groups, pyridine molecule and its derivatives, bipyridine molecule and its derivatives, terpyridine and its derivatives, organic aromatic acids and their salts, picolinic acid and its derivatives etc.

m refers to the numbers of the ligand molecules directly and chemical bonded to the cationic iron center in iron-ligand complexes. The numbers of m can be 1, 2, 3, 4, 5, or 6 respectively which depend on the selected ligands in forming metal-ligand complexes.

The iron-ligand complex catalysts are preferred. Other inorganic salts of ferric compounds also can be used as the water-soluble catalysts, such as ferric nitrate, ferric sulfate or ferric phosphate salts.

W corrosion inhibitor includes but is not limited to oligomer or polymers comprising ethyleneimine unit, propyleneimine unit, or combinations. For example, oligomer or polymer has molecular weight from about 500 to 4,000,000; 1,000 to 2,000,000; 3,000 to 200,000; 2,000 to 20,000; or 1,000 to 15,000.

The chemical additive to reduce the erosion and W trench dishing includes but is not limited to polystyrene sulfonic acid or its ammonium salt, potassium salt or sodium salt; polyacrylic acid or its ammonium salt, potassium salt or sodium salt; combinations thereof.

The polyethyleneimine (PEI) of the slurry can be either branched or linear. Preferred polyethyleneimines are branched polyethyleneimines. Preferably at least half of the polyethyleneimines are branched. Linear polyethyleneimines contain all secondary amines, in contrast to branched PEIs which contain primary, secondary and tertiary amino groups.

A branched polyethyleneimine can be represented by the formula (—NHCH₂CH₂—)ₓ[—N(CH₂CH₂NH₂)CH₂CH₂—]_{y}, where x can be 2 to >40; and y can be 2 to >40, preferably each of x and y are independently 11 to 40, alternately, each of x and y are independently 6 to 10, further alternatively x and y are independently 2-5, which is shown below:

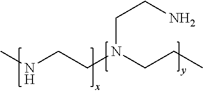

The PEI reduces static etch or erosion to essentially nil, that is, below 20 A/min. One problem with aggressive tungsten slurries is that the chemistry can attack tungsten during for example idle periods when there is no polishing, that is, no movement of abrasives sufficient to remove the oxide coating formed by the oxidizing system.

The polystyrene sulfonic acid or its ammonium salt, polyacrylic acid or its ammonium salt; or polyacrylic acid or its ammonium salt, potassium salt or sodium salt have the following general molecular structures:

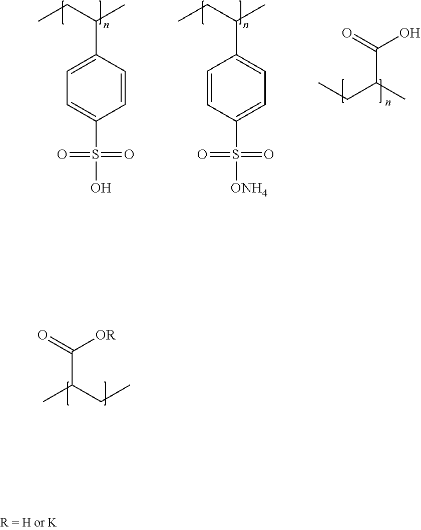

wherein, n is from 1 to 5000 for the polystyrene sulfonic acid or its ammonium salt, potassium salt or sodium salt, and n is from 1 to 20000 for polyacrylic acid or its ammonium salt, potassium salt or sodium salt.

The polystyrene sulfonic acid or its ammonium salt, potassium salt or sodium salt has molecular weight ranged from 1,000 to 2,000,000 with the preferred molecular weight ranged from 3,000 to 200,000. Also, polyacrylic acid or its ammonium salt, potassium salt or sodium salt is used as a passivating agent to reduce erosion and W trench dishing, such polyacrylic acid has molecular weight ranged from 1,000 to 4,000,000 with the preferred molecular weight ranged from 2,000 to 20,000.

Polystyrene sulfonic acid or its ammonium salt, potassium salt or sodium salt; or polyacrylic acid or its ammonium salt, potassium salt or sodium salt; ranges between 1 ppm to 10000 ppm, preferably between 25 ppm to 2500 ppm, and more preferably between 50 ppm to 500 ppm.

pH adjusting agent is used to adjust the pH of the CMP composition to the desired level.

pH adjusting agent includes but is not limited to inorganic acids, such as nitric acid, sulfonic acid, or phosphoric acid; and inorganic base, such as ammonia hydroxide, potassium hydroxide or sodium hydroxide. Nitric acid is preferred.

Suitable oxidizing agents include, but are not limited one or more per-compounds, which comprise at least one peroxy group (—O—O—).

Suitable per-compounds include but are not limited to, for example, peroxides (e.g., hydrogen peroxide and urea hydrogen peroxide), persulfates (e.g., monopersulfates and dipersulfates), percarbonates, perchlorates, perbromates, periodates, and acids thereof, and mixtures thereof, and the like, peroxyacids (e.g., peracetic acid, perbenzoic acid, m-chloroperbenzoic acid, salts thereof), mixtures thereof, and the like. Preferred oxidizing agents include hydrogen peroxide, urea-hydrogen peroxide, sodium or potassium peroxide, benzyl peroxide, di-t-butyl peroxide, peracetic acid, monopersulfuric acid, dipersulfuric acid, iodic acid, and salts thereof, and mixtures thereof. Hydrogen peroxide (H₂O₂) or periodic acid is a preferred oxidizing agent. In an embodiment, the oxidizing agent is hydrogen peroxide. Strong acid oxidizers, such as nitric acid, can also be used. Hydrogen peroxide is preferred.

The solvent which provides the principle portion of the liquid component can be water or mixtures of water with other liquids that are miscible with water. Examples of other liquids are alcohols, such as methanol and ethanol. Advantageously the solvent is water.

In one embodiment, the invention is a chemical mechanical polishing composition comprising: an abrasive suspended in a liquid to form and is between 0.1 and 20% by weight, for example between 0.5 and 5% by weight of said abrasive; an acid sufficient to provide a pH of 2.0 to 8.0, preferably acidic 2 to 6.5, 2.0 to 4, 2.0 to 3.0, or 2.0 to 2.5; a per-oxy oxidizer ranges from 1 ppm and 100000 ppm, preferably between 100 ppm to 10000 ppm, and more preferably between 500 ppm to 2500 ppm; a polyethyleneimine between 1 to 100 ppm and polystyrene sulfonic acid or polyacrylic acid, its ammonium salt, potassium salt or sodium salt ranges between 1 ppm to 10000 ppm, preferably between 25 ppm to 2500 ppm, and more preferably between 50 ppm to 500 ppm; and water. The composition is free of fluoride-containing compounds,

In another aspect, CMP polishing methods are provided for CMP polishing a substrate comprising at least one surface containing tungsten and at least one of dielectric layer or barrier layer, comprising steps of:
providing the semiconductor substrate;
providing a polishing pad;
providing the chemical mechanical polishing (CMP) composition disclosed;
contacting the surface of the semiconductor substrate with the polishing pad and the chemical mechanical polishing composition; and
polishing the surface;
wherein removal selectivity of at least one dielectric layer or barrier layer over tungsten is 1:1 to 10:1, 1.5:1 to 9:1, 2:1 to 8:1, or 2.5:1 to 6:1,

In one embodiment, the invention is a method of chemical mechanical polishing of a substrate having at least one surface containing tungsten, oxide and barrier films, such as TiN or Ti or TaN or Ta, said method comprising: movably contacting the surface with a chemical mechanical polishing composition comprising: an abrasive suspended in a liquid to form and is between 0.1 and 20% by weight, for example between 0.5 and 5% by weight of said abrasive; an acid sufficient to provide a pH of 2.0 to 8.0, 2 to 6.5, 2.0 to 4, 2.0 to 3.0, or 2.0 to 2.5; a per-oxy oxidizer ranges from 1 ppm and 100000 ppm, preferably between 100 ppm to 10000 ppm, and more preferably between 500 ppm to 2500 ppm; a polyethyleneimine between 1 to 100 ppm and polystyrene sulfonic acid or polyacrylic acid, its ammonium salt, potassium salt or sodium salt ranges between 1 ppm to 10000 ppm, preferably between 25 ppm to 2500 ppm, and more preferably between 50 ppm to 500 ppm; and water. The composition is free of fluoride-containing compounds,

The polishing removes greater than 100, 150 or 200 angstroms per minute of tungsten; greater than 500, or 700 Å/min of oxide films; and greater than 500 A/min of TiN at 3 psi.

The amount of polyethyleneimine is between 0.1 and 4 ppm, for example between 0.3 and 3 ppm. The term “ppm” means parts per million by total weight of the slurry (composition). Use of greater amounts of polyethylenimine results in reduced tungsten removal rates while there is added static etch corrosion protection.

In another aspect, CMP polishing systems are provided for CMP polishing a substrate comprising at least one surface containing tungsten and at least one of dielectric layer or barrier layer, comprising:
the semiconductor substrate;
a polishing pad;
the chemical mechanical polishing (CMP) composition disclosed above;
wherein the surface of the semiconductor substrate is contacting the polishing pad and the chemical mechanical polishing composition.

### BRIEF DESCRIPTION OF SEVERAL VIEWS OF THE DRAWINGS

In the accompanying drawing forming a material part of this description, there is shown:

FIG. 1 depicts the effect of polystyrene sulfonic acid (PSSA) on film removal rates and Erosion using solid state catalyst

FIG. 2 depicts the effects of polyethyleneimine (PEI) and polystyrene sulfonic acid (PSSA) on film RR (Å/min.) and TEOS: W selectivity using water-soluble catalyst

FIG. 3 depicts the effects of PEI and PSSA on Erosion (Å) using water-soluble catalyst

### DETAILED DESCRIPTION OF THE INVENTION

This invention involves is on the W CMP buff or barrier polishing compositions to be used for chemical mechanical polishing of a substrate comprising tungsten, oxide, and barrier films; such as TiN or Ti or TaN or Ta.

The CMP polishing composition comprises:

abrasive,

catalyst,

corrosion inhibitor for W,

chemical additive to reduce the erosion and W trench dishing,

oxidizing agent,

pH adjusting agent, and

solvent,

pH ranges are from 2.0 to 8.0, 2 to 6.5, 2.0 to 4, 2.0 to 3.0 or 2.0 to 2.5.

The abrasive includes but is not limited to alumina, ceria, germania, silica, high purity colloidal silica, titania, zirconia, composite particles abrasive such as ceria-coated silica, silica-coated alumina, and combinations thereof.

The abrasive particles have any shape, such as spherical or cocoon shapes.

The high purity colloidal silica (due to the high purity) colloidal silica are prepared from TEOS or TMOS, such high purity colloidal silica particles have very low trace metal levels, typically in the ppb levels or very low ppm level, such as <1 ppm).

Abrasive particle shapes are measured by TEM or SEM methods. The mean abrasive sizes or particle size distribution can be measured by using any suitable techniques, such as disk centrifuge (DC) method, or dynamic light scattering (DLS), colloidal dynamic method, or by Malvern Size Analyzer.

The abrasive particles have a size ranging from 20 nm to 180 nm; 30 nm to 150 nm, 35 to 80 nm, or 40 to 75 nm.

The concentrations of abrasive are ranged from 0.01 wt. % to 20 wt. %, 0.01 wt. % to 10 wt. %, 0.01 wt. % to 7.5 wt. %, 0.1 wt. % to 6.0 wt. %, 0.1 wt. % to 5.0 wt. %, 0.1 wt. % to 4.0 wt. %, 0.1 wt. % to 2.0 wt. %, 0.1 wt. % to 1.0 wt. %; which are selected for tuning film removal rates, especially tuning dielectric film removal rates.

In a preferred embodiment there is at least 0.01% by weight of an abrasive compared to the total weight of the abrasive and the liquid. The abrasive level in the slurry is not limited but preferably is less than 5%, more preferably about 4 weight percent or less, and in some embodiments is less than 1 weight percent by weight compared to the total weight of the abrasive and the liquid

In one embodiment, the abrasive is silica (colloidal silica or fumed silica). In another embodiment, the abrasive is colloidal silica.

In various embodiments, the slurry can be comprised of two or more different abrasives having different sizes. In these embodiments, the total level of abrasive is preferably less than 1 weight percent.

The catalyst includes solid-state and water soluble catalysts.

The activator or catalyst, is a material that facilitates the formation of free radicals by at least one free radical-producing compounds present in the fluid. If the activator is a metal ion, or metal-containing compound, it is in a thin layer associated with a surface of a solid which contacts the fluid. If the activator is a non-metal-containing substance, it can be dissolved in the fluid. It is preferred that the activator is present in amount that is sufficient to promote the desired

For example, activators or catalysts of U.S. Pat. Nos. 7,014,669, 6,362,104, 5,958,288, 8,241,375, 7,887,115, 6,930,054, US patent application numbers US2014315386, US2016280962, and Korean publication number KR1020110036294, the disclosure of which is incorporated by reference, can be used in this capacity.

Activator can be present in the slurry or it can be present on the polishing pad or can be present where the slurry containing oxidizer contacts the activator prior to passing between the pad and a wafer substrate.

Activators may be present in one or more different forms. Examples of different forms of activators include but not limited to (i) soluble activator compound in the slurry (ii) particle with a surface modified with activator compound (iii) particles with activator included in the both the particle core and the surface (iv) core-shell composite particles comprising activator exposed on the surface.

The solid-state catalyst includes but is not limited to Iron-coated silica or iron-coated inorganic metal oxide, such as iron-coated alumina, iron-coated titania, iron-coated zirconia, iron-coated organic polymeric nano-sized particles. These iron-coated nano-sized particles can have spherical shapes, cocoon shape, aggregate shape or any other shapes.

The solid-state catalyst has a concentrations ranged from 15 ppm to 5000 ppm, preferably from 50 ppm to 3000 ppm, and more preferably from 100 ppm to 1000 ppm.

The water soluble catalyst includes metal-ligand complexes have the general molecular structures depicted as below:

M(n+)-Lm

The metal ion M in metal-ligand complexes includes, but is not limited to, cesium, Ce, Ru, Os, Co, Rh, Ir, Ni, Pd, Pt, Cu, Ag, Au ions and other metal ions.

n+ indicates the oxidation number of metal ions in metal-ligand complexes and is 1+, 2+, or 3+ or other positive charges.

In general, the ligand molecule L used in forming metal-ligand complexes includes, but is not limited to, the organic amines, organic acids with mono-, bi-, tri-, tetra- or more carboxylic functional groups, sulfonic or phosphoric acid functional groups, organic acid salts (ammonium salts, potassium salts or sodium salts) with mono-, bi-, tri-, tetra- or more carbonate or sulfonate or phosphate functional groups, pyridine molecule and its derivatives, bipyridine molecule and its derivatives, terpyridine and its derivatives, organic aromatic acids and their salts, picolinic acid and its derivatives etc. Carboxylic functional groups are preferred.

m refers to the numbers of the ligand molecules directly and chemical bonded to the cationic iron center in iron-ligand complexes. The numbers of m can be 1, 2, 3, 4, 5, or 6 respectively which depend on the selected ligands in forming metal-ligand complexes.

The iron-ligand complex catalysts are preferred. Other inorganic salts of ferric compounds also can be used as the water-soluble catalysts, such as ferric nitrate, ferric sulfate or ferric phosphate salts.

The examples of iron-ligand complexes which are used as catalyst in the invented W CMP polishing compositions herein are listed below:

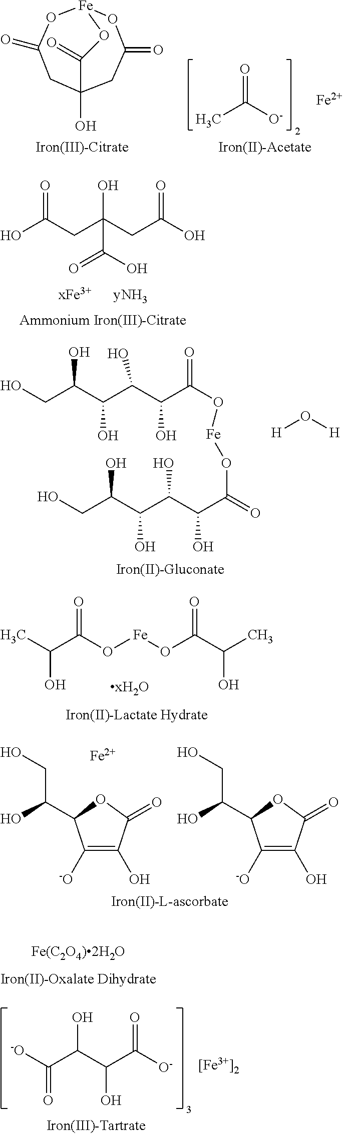

The concentration of the soluble catalyst ranges from 5 ppm to 10000 ppm, preferably from 10 ppm to 3000 ppm, and more preferably from 50 ppm to 500 ppm by weight.

W corrosion inhibitor includes but is not limited to oligomer or polymers comprising ethyleneimine unit, propyleneimine unit, or combinations.

For example, oligomer or polymer has molecular weight from about 500 to 4,000,000; 1,000 to 2,000,000; 3,000 to 200,000; 2,000 to 20,000; or 1,000 to 15,000.

The chemical additive to reduce the erosion and W trench dishing includes but is not limited to polystyrene sulfonic acid or its ammonium salt, potassium salt or sodium salt; polyacrylic acid or its ammonium salt, potassium salt or sodium salt; combinations thereof.

The polyethyleneimine (PEI) of the slurry can be either branched or linear. Preferred polyethyleneimines are branched polyethyleneimines. Preferably at least half of the polyethyleneimines are branched. Linear polyethyleneimines contain all secondary amines, in contrast to branched PEIs which contain primary, secondary and tertiary amino groups.

A branched polyethyleneimine can be represented by the formula (—NHCH₂CH₂—)ₓ[—N(CH₂CH₂NH₂)CH₂CH₂—]_{y}, where x can be 2 to >40; and y can be 2 to >40, preferably each of x and y are independently 11 to 40, alternately, each of x and y are independently 6 to 10, further alternatively x and y are independently 2-5, which is shown below:

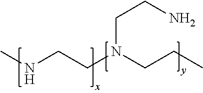

The PEI reduces static etch or erosion to essentially nil, that is, below 20 A/min. One problem with aggressive tungsten slurries is that the chemistry can attack tungsten during for example idle periods when there is no polishing, that is, no movement of abrasives sufficient to remove the oxide coating formed by the oxidizing system. In the absence of PEI, static etch for iron catalyzed peroxide systems can be as high as 200 to 300 A/min.

Concentration levels of PEI in the slurry range at point of use from 0.1 ppm to 10 ppm and preferably from 0.5 ppm to less than 5 ppm, such as from 1 ppm to 3 ppm.

The polystyrene sulfonic acid or its ammonium salt, polyacrylic acid or its ammonium salt; or polyacrylic acid or its ammonium salt, potassium salt or sodium salt have the following general molecular structures:

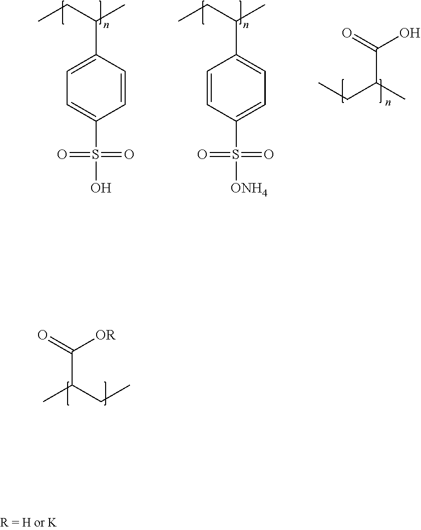

wherein, n is from 1 to 5000 for the polystyrene sulfonic acid or its ammonium salt, potassium salt or sodium salt, and n is from 1 to 20000 for polyacrylic acid or its ammonium salt, potassium salt or sodium salt.

The polystyrene sulfonic acid or its ammonium salt, potassium salt or sodium salt has molecular weight ranged from 1,000 to 2,000,000 with the preferred molecular weight ranged from 3,000 to 200,000. Also, polyacrylic acid or its ammonium salt, potassium salt or sodium salt is used as a passivating agent to reduce erosion and W trench dishing, such polyacrylic acid has molecular weight ranged from 1,000 to 4,000,000 with the preferred molecular weight ranged from 2,000 to 20,000.

Polystyrene sulfonic acid or its ammonium salt, potassium salt or sodium salt; or polyacrylic acid or its ammonium salt, potassium salt or sodium salt; ranges between 1 ppm to 10000 ppm, preferably between 25 ppm to 2500 ppm, and more preferably between 50 ppm to 500 ppm.

pH adjusting agent is used to adjust the pH of the CMP composition to the desired level.

pH adjusting agent includes but is not limited to inorganic acids, such as nitric acid, sulfonic acid, or phosphoric acid; and inorganic base, such as ammonia hydroxide, potassium hydroxide or sodium hydroxide.

Suitable oxidizing agents include, but are not limited one or more per-compounds, which comprise at least one peroxy group (—O—O—).

Suitable per-compounds include but are not limited to, for example, peroxides (e.g., hydrogen peroxide and urea hydrogen peroxide), persulfates (e.g., monopersulfates and dipersulfates), percarbonates, perchlorates, perbromates, periodates, and acids thereof, and mixtures thereof, and the like, peroxyacids (e.g., peracetic acid, perbenzoic acid, m-chloroperbenzoic acid, salts thereof), mixtures thereof, and the like. Preferred oxidizing agents include hydrogen peroxide, urea-hydrogen peroxide, sodium or potassium peroxide, benzyl peroxide, di-t-butyl peroxide, peracetic acid, monopersulfuric acid, dipersulfuric acid, iodic acid, and salts thereof, and mixtures thereof. Hydrogen peroxide (H₂O₂) or periodic acid is a preferred oxidizing agent. In an embodiment, the oxidizing agent is hydrogen peroxide. Strong acid oxidizers, such as nitric acid, can also be used. The per-oxy oxidizer or strong acid oxidizer is typically present in an amount between 1 ppm and 100000 ppm, preferably between 100 ppm to 10000 ppm, and more preferably between 500 ppm to 2500 ppm.

In an embodiment, the oxidizing agent is one per-compound (e.g., hydrogen peroxide) that is capable of forming free radicals in the presence of iron or copper compounds present in the polishing composition that results in increased tungsten removal rates.

The solvent which provides the principle portion of the liquid component can be water or mixtures of water with other liquids that are miscible with water. Examples of other liquids are alcohols, such as methanol and ethanol. Advantageously the solvent is water.

The slurry composition used in the method of this invention has a pH of 2.0 to 8.0, preferably acidic 2 to 6.5, 2.0 to 4, 2.0 to 3.0 or 2.0 to 2.5.

The presence of fluorine compounds in the slurry is not preferred as they attack the dielectrics. In a preferred embodiment, the polishing composition is free of fluoride compounds.

Some CMP patents describe a polyamine azole as a component in CMP slurry(s). It is emphasized here that a polyamine azole is not a polyethyleneimine.

The method of this invention entails use of the aforementioned composition (as disclosed supra) for chemical mechanical planarization of substrates comprised of tungsten and dielectric layer or barrier layer.

Example of dielectric layer includes but is not limited to oxide films such as TEOS, such as TEOS, PETEOS, and low-k dielectric materials; barrier/adhesion layers such as tantalum, titanium, tantalum nitride, titanium nitride, and combinations thereof.

A method of chemical mechanical polishing a semiconductor substrate containing a surface comprising tungsten and at least one of dielectric layer or barrier layer is disclosed.

In the method, a substrate (e.g., a wafer) is placed face-down toward a polishing pad which is fixedly attached to a rotatable platen of a CMP polisher. In this manner, the substrate to be polished and planarized is placed in direct contact with the polishing pad. A wafer carrier system or polishing head is used to hold the substrate in place and to apply a downward pressure against the backside of the substrate during CMP processing while the platen and the substrate are rotated. The polishing composition (slurry) is applied (usually continuously) on the pad during CMP processing to affect the removal of material to planarize the substrate.

CMP polishing methods are provided for CMP polishing a substrate comprising at least one surface containing tungsten and at least one of dielectric layer or barrier layer, comprising steps of:
providing the semiconductor substrate;
providing a polishing pad;
providing the chemical mechanical polishing (CMP) composition disclosed; contacting the surface of the semiconductor substrate with the polishing pad and the chemical mechanical polishing composition; and polishing the surface;
wherein removal selectivity of at least one dielectric layer or barrier layer over tungsten is 1:1 to 10:1, 1.5:1 to 9:1, 2:1 to 8:1, or 2.5:1 to 6:1,

In one embodiment, the invention is a method of chemical mechanical polishing of a substrate having at least one surface containing tungsten, oxide and barrier films, such as TiN or Ti or TaN or Ta, said method comprising: movably contacting the surface with a chemical mechanical polishing composition comprising: an abrasive suspended in a liquid to form and is between 0.1 and 20% by weight, for example between 0.5 and 5% by weight of said abrasive; an acid sufficient to provide a pH of 2.0 to 8.0, 2 to 6.5, 2.0 to 4, 2.0 to 3.0, or 2.0 to 2.5; a per-oxy oxidizer ranges from 1 ppm and 100000 ppm, preferably between 100 ppm to 10000 ppm, and more preferably between 500 ppm to 2500 ppm; a polyethyleneimine between 10 to 100 ppm; and polystyrene sulfonic acid or polyacrylic acid, its ammonium salt, potassium salt or sodium salt ranges between 1 ppm to 10000 ppm, preferably between 25 ppm to 2500 ppm, and more preferably between 50 ppm to 500 ppm; and water. The composition is free of fluoride-containing compounds,

The polishing removes greater than 100, 150 or 200 angstroms per minute of tungsten; greater than 500, or 700 Å/min of oxide films; and greater than 500 A/min of TiN at 3 psi.

The amount of polyethyleneimine is between 0.1 and 4 ppm, for example between 0.3 and 3 ppm. The term “ppm” means parts per million by total weight of the slurry (composition). Use of greater amounts of polyethylenimine results in reduced tungsten removal rates while there is added static etch corrosion protection.

In another aspect, CMP polishing systems are provided for CMP polishing a substrate comprising at least one surface containing tungsten and at least one of dielectric layer or barrier layer, comprising:
the semiconductor substrate;
a polishing pad;
the chemical mechanical polishing (CMP) composition disclosed above;
wherein the surface of the semiconductor substrate is contacting the polishing pad and the chemical mechanical polishing composition.

In another embodiment, the invention is a method of chemical mechanical polishing of a substrate comprising tungsten, said method comprising: movably contacting a surface of the substrate with a) an abrasive, and b) a liquid component comprising: water; an acid, preferably a mineral acid, sufficient to provide a pH of 2 to 5, for example between 2.5 and 4.5; a per-oxy oxidizer ranges between 1 ppm and 100000 ppm, preferably between 100 ppm to 10000 ppm, and more preferably between 500 ppm to 2500 ppm; a solid catalyst of an iron compound which reacts at elevated temperature with the per-oxy oxidizer to synergistically increase tungsten removal rates; and between 0.1 and 10 ppm of a polyethyleneimine, wherein in a preferred embodiment the liquid component is substantially free of carboxylic acids, and wherein the polishing removes greater than 100 angstroms per minute (“A/min”) of tungsten at 3 psi downforce and remove greater than 500 A/min of oxide film. If the iron is bound to the surface of the abrasive, then the total iron in the slurry is typically 5 ppm to 20 ppm, based on the total weight of the slurry.

In yet another embodiment, the invention is a method of chemical mechanical polishing of a substrate comprising tungsten, oxide and barrier films, such as TiN or Ti or TaN or Ta, said method comprising: movably contacting a surface having tungsten thereon with a) an abrasive suspended in a liquid to form a slurry, said slurry comprising: between 0.1 and 20% by weight, for example between 0.5 and 5% by weight of said abrasive; said liquid comprising water; an acid sufficient to provide a pH of 2 to 5; of a per-oxy oxidizer ranges from 1 ppm and 100000 ppm, preferably between 100 ppm to 10000 ppm, and more preferably between 500 ppm to 2500 ppm; between 10 to 100 ppm of a polyethyleneimine; and polystyrene sulfonic acid or its ammonium salt, potassium salt or sodium salt ranges between 1 ppm to 10000 ppm, preferably between 25 ppm to 2500 ppm, and more preferably between 50 ppm to 500 ppm. The same concentration ranges are applied for polyacrylic acid or its ammonium salt, potassium salt or sodium salt, said liquid being substantially free of fluoride-containing compounds, wherein the polishing removes greater than 100 angstroms per minute (Å/min) of tungsten and greater than 500 Å/min of oxide films.

In yet another embodiment, the invention is a method of chemical mechanical polishing of a substrate comprising tungsten, said method comprising: movably contacting a surface having tungsten thereon with a) an abrasive comprising silica, and b) a liquid component comprising water, an acid sufficient to provide a pH of 2 to 5, a per-oxy oxidizer, and between 0.1 and 10 ppm of a polyethyleneimine, and between 0.01 and 4 ppm of tetraethylenepentamine, wherein the polishing removes greater than 100 angstroms per minute of tungsten and greater than 500 Å/min of oxide films.

In another embodiment, the invention is a method of chemical mechanical polishing of a substrate comprising tungsten, oxide and barrier films, said method comprising: movably contacting a surface of the substrate with a) an abrasive, and b) a liquid component comprising water, an acid sufficient to provide a pH of 2 to 5, a per-oxy oxidizer, between 1 ppm and 60 ppm of an iron compound which reacts at elevated temperature induces free radicals from with the per-oxy oxidizer to tune tungsten removal rates, and between 0.1 and 10 ppm of a polyethyleneimine, and between 1 ppm to 1000 ppm, the preferred concentration ranges of a polyethyleneimine is between 0.05 to 500 ppm, the more preferred ranges of polyethyleneimine is between 10 to 100 ppm, polystyrene sulfonic acid or its ammonium salt, potassium salt or sodium salt concentration ranges are between 1 ppm to 10000 ppm, the preferred concentration ranges are between 25 ppm to 2500 ppm, and the more preferred concentration ranges are between 50 ppm to 500 ppm. The same concentration ranges are applied for polyacrylic acid or its ammonium salt, potassium salt or sodium salt, the same concentration ranges are applied for polyacrylic acid or its ammonium salt, potassium salt or sodium salt, and wherein the polishing removes greater than 100 angstroms per minute of tungsten and greater than 500 A/min of oxide films.

A growing trend among CMP slurry providers is the lowering of their customers' cost of consumables through product concentration. The practice of providing concentrated slurry is becoming a demand across the CMP industry. The level of concentration, however, must be prudently chosen so as not to jeopardize the stability and shelf-life time of the product.

Preferred slurries of the present invention include iron-coated silica of a first (smaller) size and silica without iron thereon of a second (larger) size. Most preferred is an embodiment also including a third abrasive of an intermediate size. As a result of having iron coated and not iron coated abrasives, certain compounds, such as carboxylic acids, should be avoided. Generally, organic materials also adversely affect aging, so the preferred total organics (excluding oxidizers) is between 0.1 and 10 ppm. Any organic corrosion inhibitor present must therefore be effective in an amount of a few ppm or less. Polyethyleneimine, especially branched polyethyleneimine, is a preferred corrosion inhibitor.

We have found that even with slurry concentrates that minimize organics, which can exacerbate long term aging effects, slurry concentrates exhibit some effects on aging, especially relating to dishing and to absolute tungsten removal rates. Note that slurry concentrates are free of oxidizers, which are added when the slurry concentrate is tank mixed with water and oxidizer to form a polishing slurry. It is known to tune slurries by adding various components thereto. The invention here is a method of mixing two different slurry concentrates (called for convenience a primary slurry concentrate and a secondary slurry concentrate), wherein the ratio of mixing of the slurry concentrates depends on the long-term age of the primary slurry concentrate, to normalize slurry performance against aging.

The present invention is further demonstrated by the examples below.

### EXAMPLES

### General

All percentages are weight percentages unless otherwise indicated.

### CMP Methodology

In the examples presented below, CMP experiments were run using the procedures and experimental conditions given below.

### Glossary

### Components

Fe-Coated Silica: Colloidal silica at 2.5 wt. % solids level having a particle size of approximately 45 nanometers (nm); the silica particles are coated with iron to an extent such that iron atoms are bound to approximately 25% of the available binding sites on the silica particles.
Col Sil: Colloidal silica particles (with varied sizes) supplied by JGC Inc. in Japan or Fuso Chemical Inc. in Japan.
Ethyleneimine Oligomer Mixture Polyethyleneimine with a minor amount of tetraethylenepentamine (>=5% and <=20% from MSDS of this product) Supplied by Sigma-Aldrich, St. Louis, Mo.

### PEI: Polyethyleneimine (Aldrich, Milwaukee, Wis.)

Polystyrene sulfonic acid Supplied by Sigma-Aldrich
Ammonium salt of Polystyrene sulfonate Supplied by Sigma-Aldrich
TEOS: tetraethylorthosilicate
Polishing Pad: Polishing pad, IC1000 and IC1010 were used during CMP, supplied by DOW, Inc.

### Parameters

### General

A or A: angstrom(s)—a unit of length
BP: back pressure, in psi units
CMP: chemical mechanical planarization=chemical mechanical polishing
CS: carrier speed
DF: Down force: pressure applied during CMP, units psi
min: minute(s)
ml: milliliter(s)
mV: millivolt(s)
psi: pounds per square inch
PS: platen rotational speed of polishing tool, in rpm (revolution(s) per minute)
SF: slurry flow, ml/min
Wt. %: weight percentage (of a listed component)
TEOS: W Selectivity: (removal rate of TEOS)/(removal rate of W)

Tungsten Removal Rates: Measured tungsten removal rate at a given down pressure. The down pressure of the CMP tool was 3.0 psi in the examples below.

TEOS Removal Rates: Measured TEOS removal rate at a given down pressure. The down pressure of the CMP tool was 3.0 psi in the examples below.

### CMP Methodology

In the examples presented below, CMP experiments were run using the procedures and experimental conditions given below

### Metrology

Tungsten films were measured with a ResMap CDE, model 168, manufactured by Creative Design Engineering, Inc, 20565 Alves Dr., Cupertino, Calif., 95014. The ResMap tool is a four-point probe sheet resistance tool. Forty nine point diameter scan at 5 mm edge exclusion for Tungsten film was taken.

### CMP Tool

The CMP tool that was used is a 200 mm Mirra, or a 300 mm Reflexion manufactured by Applied Materials, 3050 Boweres Avenue, Santa Clara, Calif., 95054. An IC1000 pad supplied by DOW, Inc, 451 Bellevue Rd., Newark, Del. 19713 was used on platen 1 for blanket and pattern wafer studies.

The IC1000 pad was broken in by conditioning the pad for 18 mins. At 7 lbs down force on the conditioner. To qualify the tool settings and the pad break-in two tungsten monitors and two TEOS monitors were polished with Versum® W5900, supplied by Versum Materials Inc. at baseline conditions.

### Wafers

Polishing experiments were conducted using CVD deposited Tungsten wafers and PECVD TEOS wafers. These blanket wafers were purchased from Silicon Valley Microelectronics, 2985 Kifer Rd., Santa Clara, Calif. 95051. The film thickness specifications are summarized below: W: 8,000 Å CVD tungsten, 240 Å TiN, 5000 Å TEOS on silicon.

### Polishing Experiments

In blanket wafer studies, tungsten blanket wafers and TEOS blanket wafers were polished at baseline conditions. The tool baseline conditions were: table speed; 120 rpm, head speed: 123 rpm, membrane pressure; 3.0 psi, inter-tube pressure; 6.0 psi, retaining ring pressure; 6.5 psi, slurry flow; 120 ml/min. or 300 ml/min.

The slurry was used in polishing experiments on patterned wafers (SKW754 or SWK854), supplied by SWK Associates, Inc. 2920 Scott Blvd. Santa Clara, Calif. 95054). These wafers were measured on the Veeco VX300 profiler/AFM instrument. The 100×100 micron line structure was used for dishing measurement, and 1×1 micron array was used for the erosion measurement. The wafer was measured at center, middle, and edge die positions.

### Example 1

In this example, the polishing was performed using CMP compositions having solid catalyst.

The slurry compositions of Example 1 shown in Table 1 were concentrated to 4× (four times the point of use concentration). Dishing and erosion data was obtained using both fresh (0 days) and aged several day samples after dilution to point of use levels.

All slurry compositions had 3.015 wt. %, colloidal silica as abrasives, 0.1005 wt. % Fe-Coated Silica, 0.1 wt. % H₂02, 0.00033 wt. % (3.3 ppm) polyethyleneimine as corrosion inhibitor, HNO₃ as pH adjusting agent. Additionally, some compositions used various concentrations of PSSA or its salt as erosion reducing chemical additive with the concentrations ranged from 100 ppm to 1000 ppm. The slurry compositions had pH around 2.1.

Sample 1 and Sample 2 were two samples having PSSA. Sample 1 had 250 ppm PSSA as 1× concentration and Sample 2 had 400 ppm PSSA as 1.6×.

Samples 3 to 5 were comparative samples having no PSSA.

The removal rates on W and TEOS (Ox), W erosion and W plug recess were tested using the slurries. The results were shown in Table 1.

TABLE 1
Effect of PSSA on Erosion in W Buff Slurries

| | | | | W | |
|---|---|---|---|---|---|
| Slurry | PSSA | W RR | Ox RR | recess | Erosion |
| Sample | (ppm) | (Å/min.) | (Å/min.) | (Å) | (Å) |
| 1 | 250 | 66 | 584 | −28 | 200 |
| 2 | 400 | ~150 | ~800 | −32 | 120 |
| 3 | 0 | 226 | 960 | −29 | 300 |
| 4 | 0 | 310 | 944 | −24 | 320 |
| 5 | 0 | 513 | 1013 | −17 | 350 |

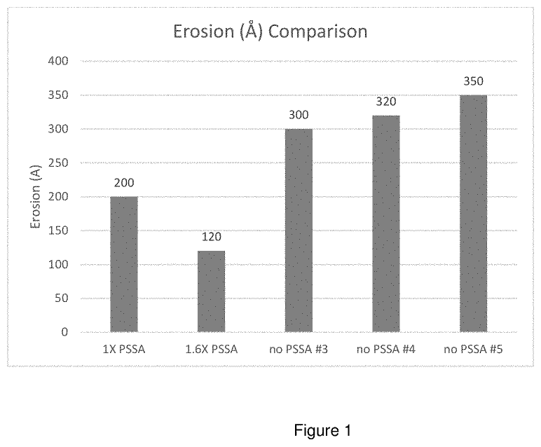

The results in Table 1, also shown in FIG. 1, clearly showed that the two samples using PSSA had significant erosion reductions while remaining very low W plug recess.

The W CMP buffering polishing compositions also provided high and tunable TEOS film removal rates, high and tunable barrier film, such as TiN film, removal rates, and tunable W film removal rates.

TEOS: W Selectivity: (removal rate of TEOS)/(removal rate of W) obtained from the W CMP buffering polishing compositions were tunable and ranged from 2:1 to 9:1; potentially 1:1 to 10:1.

A growing trend among CMP slurry providers is the lowering of their customers' cost of consumables through product concentration. The practice of providing concentrated slurry is becoming a demand across the CMP industry. The level of concentration, however, must be prudently chosen so as not to jeopardize the stability and shelf-life time of the product. The slurry composition of Examples in Table 1 was concentrated to 4X (four times the point of use concentration). Dishing and erosion data was obtained using both fresh (0 days) and aged several day samples after dilution to point of use levels.

### Example 2

In this example, the polishing was performed using CMP compositions having soluble iron-ligand catalyst.

In the example, tungsten blanket wafers and TEOS blanket wafers were polished at baseline conditions. The tool baseline conditions were: table speed; 120 rpm, head speed: 123 rpm, membrane pressure; 3.0 psi, inter-tube pressure; 3.0 psi, retaining ring pressure; 7.5 psi, slurry flow; 120 ml/min.

All samples had pH adjusted to 2.1 using nitric acid HNO₃.

The reference Sample 1 comprised 100 ppm iron-gluconate hydrate, 500 ppm gluconic acid, 4.0 wt. % colloidal silica as abrasives, and 0.15 wt. % H₂O₂ was used as oxidizing agent (at the point of use).

All other samples had all chemical components in reference Sample 1, and additional component(s).

Sample 2 used 0.00033 wt. % polyethyleneimine (PEI) as corrosion inhibitor.

Sample 3 and 4 both used PSSA in acid form as film removal rate and oxide: W selectivity tuning agent at 0.025 wt. % and 0.04 wt. % respectively.

Sample 5 used 0.00033 wt. % polyethyleneimine (PEI) as corrosion inhibitor and 0.025 wt. % PSSA in acid form as film removal rate and oxide: W selectivity tuning agent.

Sample 6 used 0.00033 wt. % polyethyleneimine (PEI) as corrosion inhibitor and 0.04 wt. % PSSA in acid form as film removal rate and oxide: W selectivity tuning agent.

Sample 7 used 0.00033 wt. % polyethyleneimine (PEI) as corrosion inhibitor; 0.06 wt. % PSSA in acid form as film removal rate and oxide: W selectivity tuning agent.

All samples had pH adjusted to 2.1 using nitric acid HNO₃.

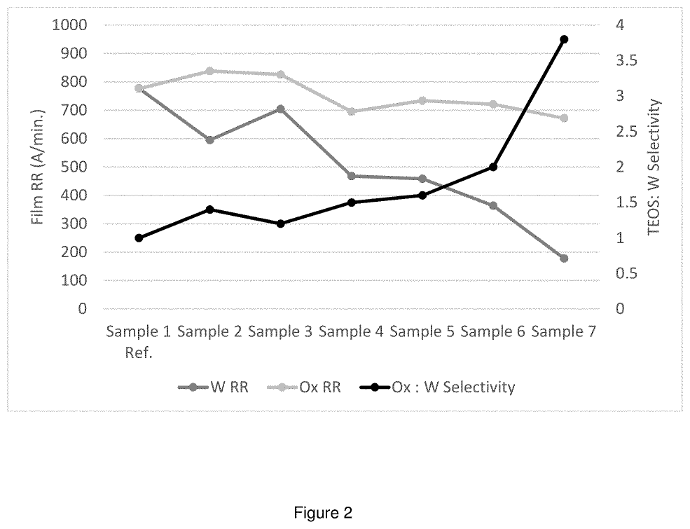

The blanket wafer polishing test results were listed in Table 2 and depicted in FIG. 2.

TABLE 2
Effects of PEI and PSSA on Film
RR (A/min.) & TEOS:W Selectivity

| | Corrosion | | | | |
|---|---|---|---|---|---|
| | Inhibitor | | | | |
| | PEI | PSSA | W RR | Ox RR | Ox:W |
| Slurry | (ppm) | (ppm) | (Å/min.) | (Å/min.) | Selectivity |
| Sample 1 | | | 812 | 802 | 1 |
| Ref. | | | | | |
| Sample 2 | 3.3 | | 652 | 821 | 1.3 |
| Sample 3 | | 250 | 693 | 727 | 1.05 |
| Sample 4 | | 400 | 564 | 718 | 1.3 |
| Sample 5 | 3.3 | 250 | 496 | 739 | 1.5 |
| Sample 6 | 3.3 | 400 | 353 | 722 | 2 |
| Sample 7 | 3.3 | 600 | 156 | 737 | 4.7 |

As the results shown in Table 2 and FIG. 2, when the corrosion inhibitor PEI was used alone (i.e., no PSSA) in the formulations, W removal rates were suppressed by different percentages, and oxide film removal rate was increased.

The oxide film removal rates were slightly reduced while using PSSA alone (i.e., no PEI). And, the oxide: W selectivity were slightly increased.

When both PEI and PSSA additives were used in the formulations, the W removal rates were further suppressed, and oxide removal rates were slightly suppressed while comparing to the removal rates obtained from reference sample.

When keeping the same corrosion inhibitor concentration while increasing PSSA concentration, the W removal rate was further reduced, to 156 A/min. The oxide: W selectivity was increased to 4.7:1.

Data also indicated that W removal rates can be further suppressed by increasing PSSA additive concentrations. Thus, TEOS: W Selectivity: (removal rate of TEOS)/(removal rate of W) were tunable and ranged from 1:1 to 5:1; potentially 1:1 to 10:1.

### Example 3

In this example, the effects of the corrosion inhibitor, PEI, and the selectivity tuning agent, PSSA, while used alone or used together, on the erosion of polishing W patterned wafers were examined.

20% over time polishing were used for polishing the pre-polished and prepared W patterned wafer using the same slurry formulations listed in Table 2.

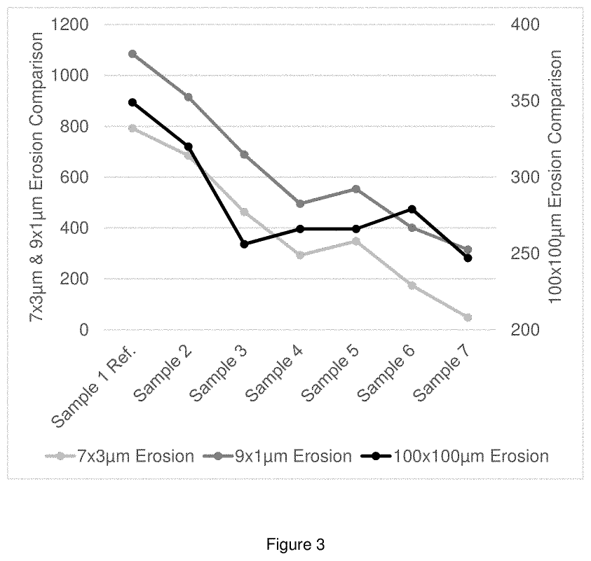

The erosion data were listed in Table 3 and depicted in FIG. 3.

TABLE 3
Effects of PEI and PSSA on Erosion (Å)

| | Corrosion | | | | |
|---|---|---|---|---|---|
| | Inhibitor | | 100 × 100 μm | 7 × 3 μm | 9 × 1 μm |
| | PEI | PSSA | Erosion | Erosion | Erosion |
| Slurry | (ppm) | (ppm) | (Å) | (Å) | (Å) |
| Sample 1 | | | 349 | 792 | 1085 |
| Ref. | | | | | |
| Sample 2 | 3.3 | | 320 | 685 | 915 |
| Sample 3 | | 250 | 256 | 463 | 689 |
| Sample 4 | | 400 | 266 | 293 | 495 |
| Sample 5 | 3.3 | 250 | 266 | 348 | 553 |
| Sample 6 | 3.3 | 400 | 279 | 174 | 401 |
| Sample 7 | 3.3 | 600 | 247 | 48 | 315 |

When the corrosion inhibitor PEI was used alone (i.e., no PSSA), the erosions on 50%, 70%, and 90% density features were slightly reduced.

When the selectivity tuning agent PSSA was used alone in the formulations (i.e., no PEI), The erosions on 50%, 70%, and 90% density features were significantly reduced.

When both PEI and PSSA additives were used in the same formulations, the erosion of 50% large 100×100 μm feature were all significantly reduced while comparing to the erosion values obtained for the reference sample without using PEI and PSSA.

When keeping the same corrosion inhibitor concentration while increasing PSSA concentration, the erosion of 50% large 100×100 μm feature large feature remained low. When PSSA concentrations increased from 250 ppm to 400 ppm at point of use further reduced erosion on 70% and 90% density features.

When using 0.0003 wt. % PEI and 0.06 wt. % PSSA as corrosion inhibitor and selectivity tuning agent (Sample 7), the erosions on 50%, 70%, and 90% density features were reduced from 349 Å, 792 Å, and 1085 Å obtained for the reference sample to 247 Å, 48 Å, and 315 Å which represented significant erosion reductions while using water-soluble iron compounds as catalyst, PEI as corrosion inhibitor, and PSSA as selectivity tuning agent.

The embodiments of this invention listed above, including the working example, are exemplary of numerous embodiments that may be made of this invention. It is contemplated that numerous other configurations of the process may be used, and the materials used in the process may be elected from numerous materials other than those specifically disclosed.

1. A chemical-mechanical planarization (CMP) composition comprising:
0.1 wt. % to 10 wt. % abrasive selected from the group consisting of alumina, ceria, germania, silica, titania, zirconia, a metal-modified abrasive, such as iron-coated silica, and combinations thereof,
50 ppm to 3000 ppm solid state or water soluble catalyst,
0.1 ppm to 10 ppm corrosion inhibitor for W selected from the group consisting of an oligomer or polymer comprising ethyleneimine unit, propyleneimine unit, and combinations thereof; wherein the molecular weight of the polymer is about 500 to 1000000;
25 ppm to 2500 ppm chemical additive selected from the group consisting of (1) polystyrene sulfonic acid or its ammonium salt, potassium salt or sodium salt has molecular weight ranged from 1,000 to 2,000,000; (2) polyacrylic acid or its ammonium salt, potassium salt or sodium salt has molecular weight ranged from 1,000 to 4,000,000; and (3) combinations thereof;
oxidizing agent;
pH adjusting agent, and
solvent,
the composition has a pH from 2 to 6.5.

2. The chemical-mechanical planarization (CMP) composition of claim 1, wherein the solid state catalyst is selected from the group consisting of iron-coated silica, iron-coated alumina, iron-coated titania, iron-coated zirconia, iron-coated organic polymeric nano-sized particle, iron-coated inorganic metal oxide, and combination thereof.

3. The chemical-mechanical planarization (CMP) composition of claim 1, wherein the water soluble catalyst includes metal-ligand complexes have the general molecular structures depicted as below:
M(n+)-Lm,
wherein
M is selected from the group consisting of Cs, Ce, Ru, Os, Co, Rh, Ir, Ni, Pd, Pt, Cu, Ag, and Au ion;
n+ indicates the oxidation number of metal ions and is 1+, 2+, or 3+;
ligand molecule L is selected from the group consisting of organic amine; organic acids with mono-, bi-, tri-, tetra-carboxylic acid functional group; sulfonic or phosphoric acid functional group; organic acid salts selected from ammonium salts, potassium salts or sodium salts with mono-, bi-, tri-, tetra-carbonate, sulfonate or phosphate functional groups; pyridine molecule and its derivatives; bipyridine molecule and its derivatives; terpyridine and its derivatives; organic aromatic acids and their salts; picolinic acid and its derivatives; and combinations thereof;
m refers to number of the ligand molecules directly and chemical bonded to the cationic iron center in iron-ligand complexes; and m can be 1, 2, 3, 4, 5, or 6 respectively which depend on the selected ligands in forming metal-ligand complexes.

4. The chemical-mechanical planarization (CMP) composition of claim 3, wherein the metal-ligand complexes are iron-ligand complexes selected from the group consisting of 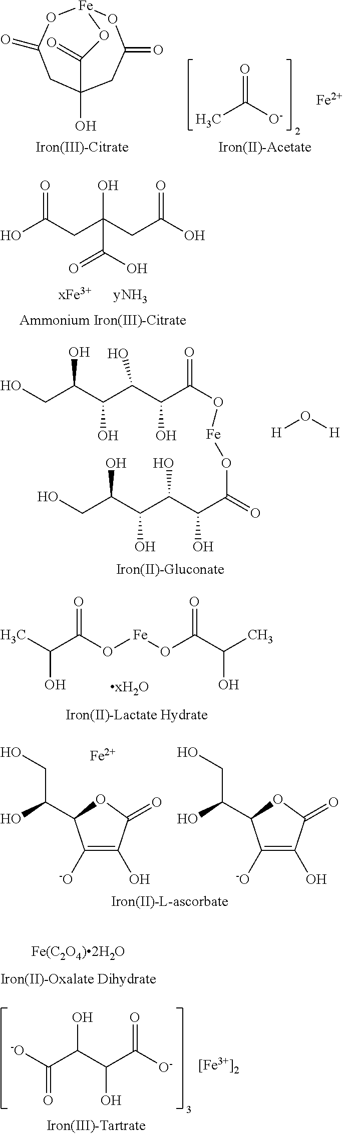
and combinations thereof.

5. The chemical-mechanical planarization (CMP) composition of claim 1, wherein the corrosion inhibitor for W is polyethyleneimine having a concentration of from 1 ppm to 500 ppm; wherein the polyethyleneimine (PEI) can be either branched or linear; wherein the branched polyethyleneimines is represented by the formula (—NHCH₂CH₂—)ₓ[—N(CH₂CH₂NH₂)CH₂CH₂—]_{y} shown below: 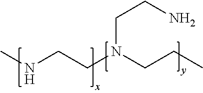
wherein x and y are independently 11 to 40.

6. The chemical-mechanical planarization (CMP) composition of claim 1, wherein the polystyrene sulfonic acid or its ammonium salt, potassium salt or sodium salt; or polyacrylic acid or its ammonium salt, potassium salt or sodium salt have the following general molecular structures: 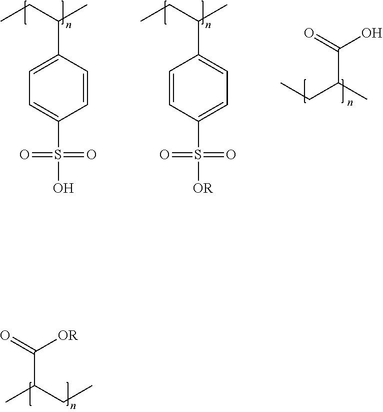
wherein, R is Na⁺, K⁺ or NH₄⁺; n is from 1 to 5000 for the polystyrene sulfonic acid or its ammonium salt, potassium salt or sodium salt, and n is from 1 to 20000 for polyacrylic acid or its ammonium salt, potassium salt or sodium salt.

7. The chemical-mechanical planarization (CMP) composition of claim 1, wherein the oxidizing agent is selected from the group consisting of per-oxy oxidizer comprising at least one peroxy group (—O—O—) selected from the group consisting of H₂O₂ and urea hydrogen peroxide, sodium or potassium peroxide, benzyl peroxide, di-t-butyl peroxide, persulfates, percarbonates, perchlorates, perbromates, periodates, and acids thereof; peroxyacids, peracetic acid, monopersulfuric acid, and dipersulfuric acid; iodic acid and salts thereof; nitric acid; combinations thereof.

8. The chemical-mechanical planarization (CMP) composition of claim 1, wherein the pH adjusting agent is selected from the group consisting of (1) inorganic acid selected from the group consisting of nitric acid, sulfonic acid, phosphoric acid and combinations thereof; (2) inorganic base selected from the group consisting of ammonia hydroxide, potassium hydroxide, sodium hydroxide and combinations thereof.

9. The chemical-mechanical planarization (CMP) composition of claim 1, wherein the solvent is selected from the group consisting of water, a liquid that is miscible with water.

10. The chemical-mechanical planarization (CMP) composition of claim 1, wherein the composition comprises colloidal silica, Fe-coated silica or iron gluconate, H₂O₂, polyethyleneimine, polystyrene sulfonic acid (PSSA), nitric acid, and water, and pH of 2.0 to 3.5.

11. A method of chemical mechanical polishing a semiconductor substrate containing a surface comprising tungsten and at least one of dielectric layer or barrier layer, comprising steps of:
providing the semiconductor substrate;
providing a polishing pad;
providing a chemical mechanical polishing (CMP) composition comprising:
0.1 wt. % to 6 wt. % abrasive selected from the group consisting of alumina, ceria, germania, silica, titania, zirconia, a metal-modified abrasive, such as iron-coated silica, and combinations thereof,
50 ppm to 3000 ppm solid state or water soluble catalyst,
0.1 ppm to 10 ppm corrosion inhibitor for W selected from the group consisting of an oligomer or polymer comprising ethyleneimine unit, propyleneimine unit, and combinations thereof; wherein the molecular weight of the polymer is about 500 to over 1000000, preferably about 1000 to 500000;
25 ppm to 2500 ppm chemical additive selected from the group consisting of (1) polystyrene sulfonic acid or its ammonium salt, potassium salt or sodium salt has molecular weight ranged from 1,000 to 2,000,000; (2) polyacrylic acid or its ammonium salt, potassium salt or sodium salt has molecular weight ranged from 1,000 to 4,000,000; and (3) combinations thereof;
oxidizing agent;
pH adjusting agent; and
solvent;
the composition has a pH from 2 to 6.5;
contacting the surface of the semiconductor substrate with the polishing pad and the chemical mechanical polishing composition; and
polishing the surface of the semiconductor;
wherein removal selectivity of at least one dielectric layer or barrier layer over tungsten is between 1 and 10.

12. The method of claim 11, wherein the at least one dielectric layer or barrier layer is a dielectric layer comprising an oxide film, removal rate for tungsten is greater than 100 A/min, removal rate for the oxide film is greater than 500 A/min at 3 psi.

13. The method of claim 11, wherein removal rate for tungsten is greater than 100 A/min, preferably greater than 150 A/min at 3 psi down force, and more preferably greater than 200 A/min; removal rate for the dielectric layer is greater than 500 A/min at 3 psi, preferably greater than 700 A/min.

14. The method of claim 11, wherein the solid state catalyst is selected from the group consisting of iron-coated silica, iron-coated alumina, iron-coated titania, iron-coated zirconia, iron-coated organic polymeric nano-sized particle, iron-coated inorganic metal oxide, and combination thereof; and the water soluble catalyst includes metal-ligand complexes have the general molecular structures depicted as below:
M(n+)-Lm,
wherein
M is selected from the group consisting of Cs, Ce, Ru, Os, Co, Rh, Ir, Ni, Pd, Pt, Cu, Ag, and Au ion;
n+ indicates the oxidation number of metal ions and is 1+, 2+, or 3+;
ligand molecule L is selected from the group consisting of organic amine; organic acids with mono-, bi-, tri-, tetra-carboxylic functional groups; sulfonic or phosphoric acid functional group; organic acid salts selected from ammonium salts, potassium salts or sodium salts with mono-, bi-, tri-, tetra-carbonate, sulfonate or phosphate functional groups; pyridine molecule and its derivatives; bipyridine molecule and its derivatives; terpyridine and its derivatives; organic aromatic acids and their salts; picolinic acid and its derivatives; and combinations thereof;
m refers to number of the ligand molecules directly and chemical bonded to the cationic iron center in iron-ligand complexes; and m can be 1, 2, 3, 4, 5, or 6 respectively which depend on the selected ligands in forming metal-ligand complexes.

15. The method of claim 14, wherein the metal-ligand complexes are iron-ligand complexes selected from the group consisting of 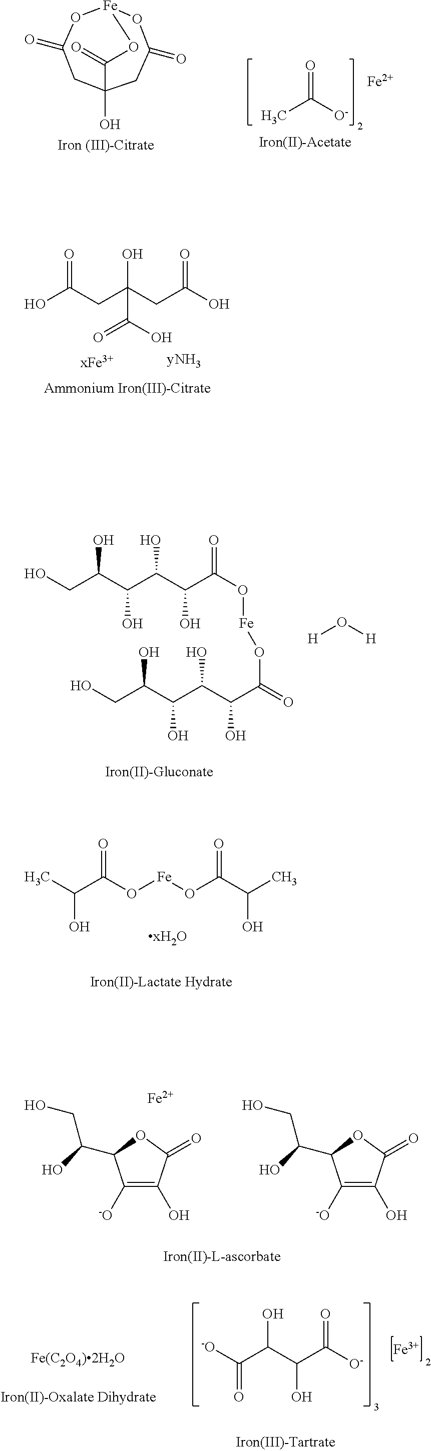
and combinations thereof.

16. The method of claim 11, wherein the corrosion inhibitor for W is polyethyleneimine having a concentration of from 1 ppm to 500 ppm; wherein the polyethyleneimine (PEI) can be either branched or linear; wherein the branched polyethyleneimines is represented by the formula (—NHCH₂CH₂—)ₓ[—N(CH₂CH₂NH₂)CH₂CH₂—]_{y} shown below: 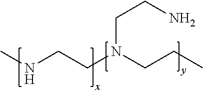
wherein x and y are independently 11 to 40.

17. The method of claim 11, wherein the polystyrene sulfonic acid or its ammonium salt, potassium salt or sodium salt; or polyacrylic acid or its ammonium salt, potassium salt or sodium salt have the following general molecular structures: 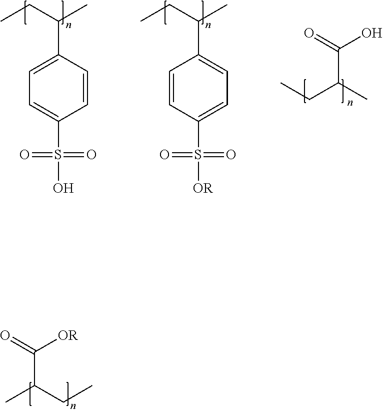
wherein, R is Na⁺, K⁺ or NH₄⁺; n is from 1 to 5000 for the polystyrene sulfonic acid or its ammonium salt, potassium salt or sodium salt, and n is from 1 to 20000 for polyacrylic acid or its ammonium salt, potassium salt or sodium salt.

18. The method of claim 11, wherein the oxidizing agent is selected from the group consisting of per-oxy oxidizer comprising at least one peroxy group (—O—O—), H₂O₂ and urea hydrogen peroxide, sodium or potassium peroxide, benzyl peroxide, di-t-butyl peroxide, persulfates, percarbonates, perchlorates, perbromates, periodates, and acids thereof; peroxyacids, peracetic acid, monopersulfuric acid, dipersulfuric acid, iodic acid, and salts thereof; nitric acid; combinations thereof.

19. The method of claim 11, wherein the pH adjusting agent is selected from the group consisting of (1) inorganic acid selected from the group consisting of nitric acid, sulfonic acid, phosphoric acid and combinations thereof; (2) inorganic base selected from the group consisting of ammonia hydroxide, potassium hydroxide, sodium hydroxide and combinations thereof.

20. The method of claim 11, wherein the solvent is selected from the group consisting of water, a liquid that is miscible with water.

21. The method of claim 11, wherein the composition comprises colloidal silica, Fe-coated silica or iron gluconate, H₂O₂, polyethyleneimine, polystyrene sulfonic acid (PSSA), nitric acid, and water, and pH of 2.0 to 3.5.

22. A systems of chemical mechanical polishing a semiconductor substrate containing a surface comprising tungsten and at least one of dielectric layer or barrier layer, comprising:
the semiconductor substrate;
a polishing pad;
a chemical mechanical polishing (CMP) composition comprising:
0.1 wt. % to 6 wt. % abrasive selected from the group consisting of alumina, ceria, germania, silica, titania, zirconia, a metal-modified abrasive, such as iron-coated silica, and combinations thereof,
50 ppm to 3000 ppm solid state or water soluble catalyst,
0.1 ppm to 10 ppm corrosion inhibitor for W selected from the group consisting of an oligomer or polymer comprising ethyleneimine unit, propyleneimine unit, and combinations thereof; wherein the molecular weight of the polymer is about 500 to over 1000000, preferably about 1000 to 500000;
25 ppm to 2500 ppm chemical additive selected from the group consisting of (1) polystyrene sulfonic acid or its ammonium salt, potassium salt or sodium salt has molecular weight ranged from 1,000 to 2,000,000; (2) polyacrylic acid or its ammonium salt, potassium salt or sodium salt has molecular weight ranged from 1,000 to 4,000,000; and (3) combinations thereof;
oxidizing agent;
pH adjusting agent; and
solvent;
the composition has a pH from 2 to 6.5;
wherein the surface of the semiconductor substrate is contacting the polishing pad and the chemical mechanical polishing composition.
